(19) United States
(12) Patent Application Publication
(10) Pub. No.: US 2009/0065182 A1
(43) Pub. Date: Mar. 12, 2009

(54) COOLING DEVICE

(75) Inventors: Tetsuya Takahashi, Tokyo (JP); Kazuyoshi Toya, Tokyo (JP); Akihiro Murahashi, Tokyo (JP); Yasushi Nakayama, Tokyo (JP); Shigetoshi Ipposhi, Tokyo (JP); Kenichi Hayashi, Tokyo (JP)

Correspondence Address: BUCHANAN, INGERSOLL & ROONEY PC, POST OFFICE BOX 1404, ALEXANDRIA, VA, 22313-1404, US

(73) Assignee: MITSUBISHI ELECTRIC CORPORATION, Chiyoda-ku (JP)

(21) Appl. No.: 12/293,139

(22) PCT Filed: Mar. 31, 2006
(86) PCT No.: PCT/JP2006/306813

§ 371 Date: Sep. 16, 2008

(51) Int. Cl. F28D 15/00; H05K 7/20

(52) U.S. Cl. 165/104.33; 165/121; 361/701

(57) ABSTRACT

There is provided a cooling device which includes a plurality of cooling modules 6 having cooling units 6A for cooling heat-generating elements 7 by coolant and radiation units 6C for radiating heat from the coolant heated in the cooling units 6A, the plurality of cooling modules being bubble-pump-type ones in which the coolant is circulated between the radiation units 6C and the cooling units 6A by the coolant being boiled in the cooling units 6A, the radiation units 6C being arranged side by side, and a cooling fan 2 for generating wind blowing the radiation units 6C.

### TECHNICAL FIELD

The present invention relates to cooling devices for cooling heat-generating elements such as semiconductor devices.

### BACKGROUND ART

An electric power conversion apparatus such as a converter or an inverter that performs a switching operation by a semiconductor device is used as an electric power source for an electric motor in general industrial fields. A semiconductor device such as an IGBT (insulated gate bipolar transistor), a thyristor, a transistor, or a diode used in an electric power conversion apparatus such as a converter or an inverter generates heat, and the amount of the heat generation also increases with increase of the output power; accordingly, effective cooling of the semiconductor device is important. Here, an IPM (intelligent power module) configured of a semiconductor device modularized with a driving circuit is supposed to be also referred to as a semiconductor device.

In a conventional cooling device, a system has been practically used in which a heat pipe is utilized. The heat pipe has a structure in which coolant sealed in a tube stood in the vertical orientation; a target to be cooled is contacted with a lower portion of the tube; and a fin or like heat-dissipative structure is provided in its upper portion. The coolant sealed in the tube is vaporized in the lower portion by the heat received from the target to be cooled. The vaporized coolant moves toward the upper portion of the tube, and then returns to the liquid state with losing its heat at the upper portion of the tube, and thereafter the liquid-state coolant, after flowing along the inside wall of the tube, is accumulated at the lower portion. The accumulated coolant is again vaporized. As described above, in the heat pipe, by vaporizing the coolant, the heat is transferred from the lower to the upper portion, and is then dissipated from the upper portion to the outside, whereby the target to be cooled that is contacted with the lower portion is cooled.

In a cooling device using a heat pipe, a circuit board on which a semiconductor device that generates heat is mounted is horizontally arranged so that the semiconductor device faces downward, whereby the heat pipe is placed to contact with the upward-facing bottom face of the circuit board (for example, refer to Patent Document 1).

A cooling device used for an electric power conversion apparatus for an electric rolling stock has also been practically used, which includes a heat-receiving plate, having a flow channel for flowing cooling liquid therethrough, to which a semiconductor device is attached, a heat exchanger for exchanging heat between the cooling liquid from the heat-receiving plate and the air, a pump for circulating the cooling liquid between the heat-receiving plate and the heat exchanger, and a blowing means for blowing cooling wind to the heat exchanger, and in which plural sets of the heat-receiving plates, the heat exchangers, the pumps, and the blowing means are collinearly arranged perpendicularly to the longitudinal orientation of the car body. This cooling device is configured in such a way that wind is introduced through the side face of the car body, the blowing means and the heat-receiving plate are together in parallel to the longitudinal orientation of the car body, and face to each other, and the heat exchanger and the heat-receiving plate arranged in the longitudinal orientation of the car body are positioned perpendicularly to each other (for example, refer to Patent Document 2).

[Patent Document 1]

Japanese Laid-Open Patent Publication No. 2002-134670

[Patent Document 2]

Japanese Laid-Open Patent Publication No. 1997-246767

### DISCLOSURE OF THE INVENTION

### [Problems to be Solved by the Invention]

In the cooling device using the heat pipe, the heat pipe is needed to be vertically arranged, and the circuit board is needed to be horizontally arranged, and thus a height equals to or more than approximately 10 cm is needed for the heat pipe; therefore, it has been difficult that the circuit boards are arranged in overlapping relation. The amount of heat generation of the semiconductor device and the area needed for mounting the semiconductor device are determined, and thus the height and the volume of the heat pipe are determined by the heat generation amount per unit area; therefore, a predetermined volume has also been needed for the cooling device to meet the circuit board having a predetermined amount of heat generation.

In the cooling device in which the cooling liquid is circulated using the pump, a space has been needed for an attachment such as the pump and a reserve tank for the cooling liquid. Moreover, the heat exchanger and the heat-receiving plate are placed perpendicularly to each other, and a predetermined area is needed for the heat exchanger; therefore, a set of the heat-receiving plate, the heat exchanger, the pump, and the blowing means could not have been arranged with a particularly small gap.

An objective of the present invention is to obtain a cooling device whose volume needed to realize a predetermined coolability level is smaller than that of the conventional one.

### [Means for Solving the Problem]

A cooling device according to the present invention includes a plurality of cooling modules, each having a cooling unit for cooling a heat generating element by coolant and a radiation unit for radiating heat from the coolant heated in the cooling unit, as bubble-pump-type ones in which the coolant is circulated between the radiation unit and the cooling unit by the coolant being boiled in the cooling unit, the radiation units being arranged side by side, and a cooling fan for generating wind blowing the radiation unit.

### [Advantageous Effect of the Invention]

The cooling device according to the present invention includes the plurality of cooling modules, each having the cooling unit for cooling the heat generating element by the coolant and the radiation unit for radiating heat from the coolant heated in the cooling unit, as the bubble-pump-type ones in which the coolant is circulated between the radiation unit and the cooling unit by the coolant being boiled in the cooling unit, the radiation units being arranged side by side, an effect is obtained that the volume, needed to realize a predetermined coolability level, of an apparatus is smaller than that of the conventional one.

### BRIEF DESCRIPTION OF DRAWINGS

FIG. 1 is views of a state in which an electric power conversion apparatus using a cooling device according to Embodiment 1 of the present invention is attached to an electric car;

FIG. 2 is perspective views explaining a configuration of the electric power conversion apparatus using the cooling device according to Embodiment 1 of the present invention;

FIG. 3 is a cross-sectional view explaining the configuration of the electric power conversion apparatus using the cooling device according to Embodiment 1 of the present invention;

FIG. 4 is a perspective view illustrating a cooling module with semiconductor devices mounted thereon, for constituting the electric power conversion apparatus using the cooling device according to Embodiment 1 of the present invention;

FIG. 5 is a view explaining a configuration of the cooling module used in the cooling device and the flow of coolant therethrough according to Embodiment 1 of the present invention;

FIG. 6 is a perspective view explaining a configuration of an electric power conversion apparatus using a cooling device according to Embodiment 2 of the present invention;

FIG. 7 is a perspective view explaining a configuration of an electric power conversion apparatus using a cooling device according to Embodiment 3 of the present invention;

FIG. 8 is a plan view explaining the configuration of the electric power conversion apparatus using the cooling device according to Embodiment 3 of the present invention, viewed from the bottom of the apparatus;

FIG. 9 is a perspective view explaining a configuration of an electric power conversion apparatus using a cooling device according to Embodiment 4 of the present invention;

FIG. 10 is a plan view explaining the configuration of the electric power conversion apparatus using the cooling device according to Embodiment 4 of the present invention, viewed from the bottom of the apparatus; and

FIG. 11 is a cross-sectional view explaining the configuration of the electric power conversion apparatus using the cooling device according to Embodiment 4 of the present invention.

### EXPLANATION OF REFERENCES

100: Electric power conversion apparatus

1: Main circuit unit

1A: Case (Fixing member)

1B: Aperture

1C: Filter

2: Blower (Cooling fan)

3: Electrical component

4: Duct (Wind tunnel)

5: Capacitor

6: Cooling module

6A: Cooling unit

6B: Heat exchanger

6C: Radiation unit

6D: Heat-receiving tube

6E: Pipe

6F: Partition

6G: Pipe

6H: Pipe

6J: Pipe

6K: Heat radiation pipe

6L: Heat radiation fin

7: Semiconductor device

8: Wiring board

### BEST MODE FOR CARRYING OUT THE INVENTION

### Embodiment 1

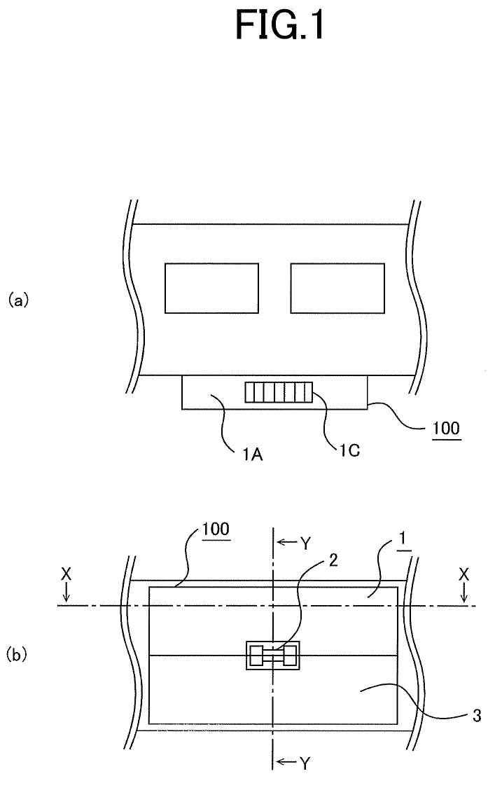

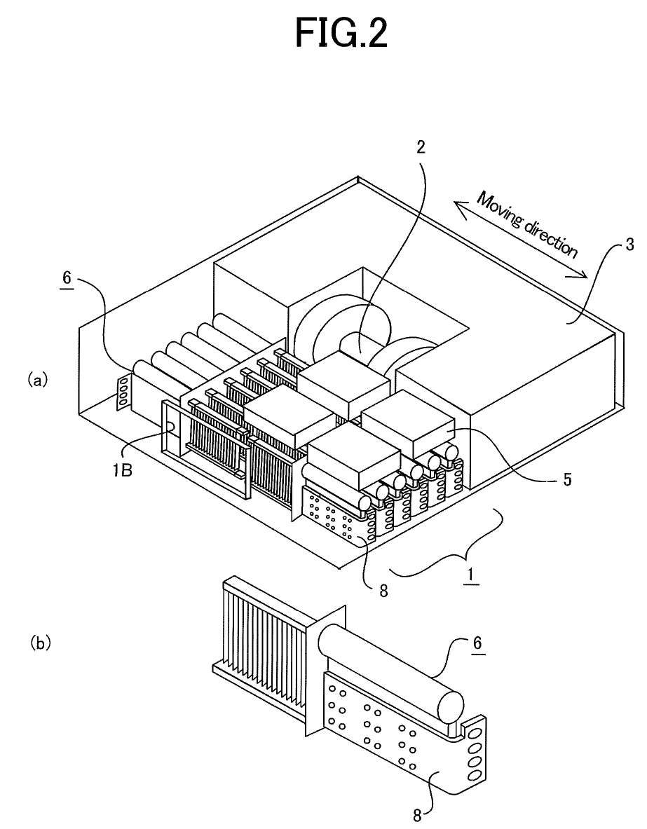

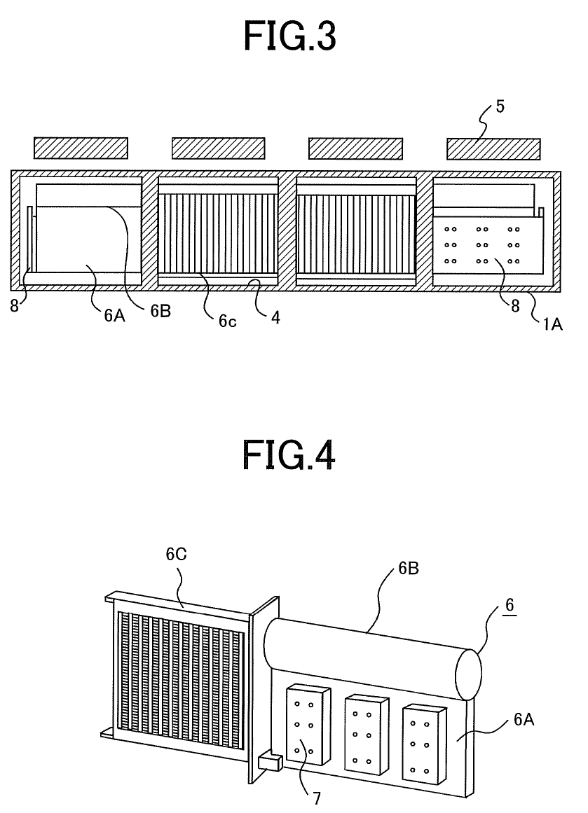

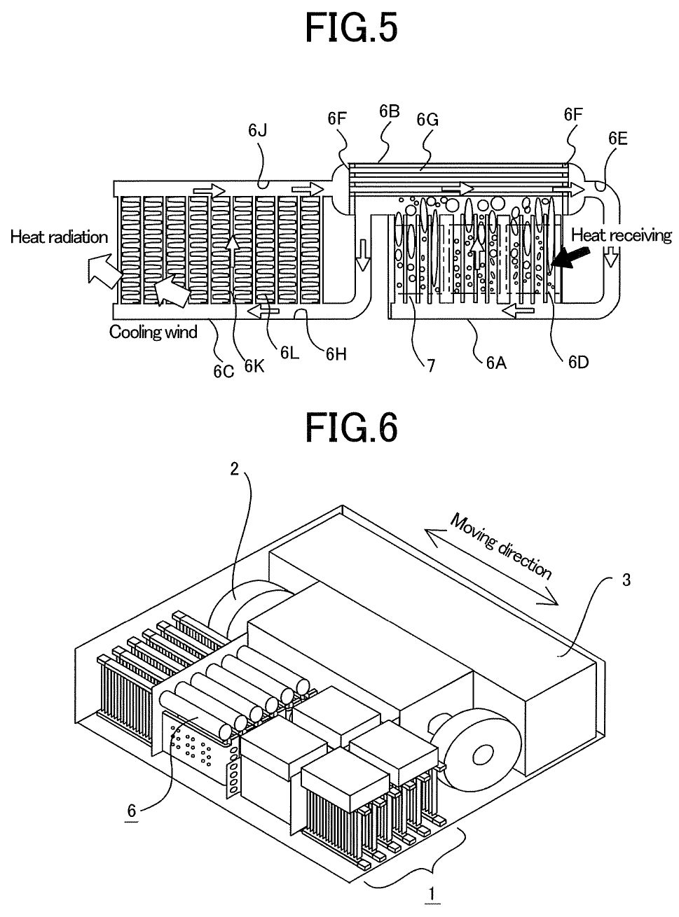

A case is explained using FIG. 1-FIG. 5, in which a cooling device according to Embodiment 1 of the present invention is applied to an electric power conversion apparatus having a converter and an inverter for an electric car. FIG. 1 is a view explaining the electric power conversion apparatus using the cooling device according to Embodiment 1. Its side view is illustrated in FIG. 1(a), while its plan view viewed from its bottom is illustrated in FIG. 1(b). FIG. 2 is a perspective view explaining a configuration of the electric power conversion apparatus using the cooling device according to Embodiment 1. A perspective view of the entire configuration is illustrated in FIG. 2(a), and that of a single cooling module on which a predetermined number of semiconductor devices is mounted is illustrated in FIG. 2(b). A cross-sectional view of the X-X cross section according to FIG. 1(b) is illustrated in FIG. 3. FIG. 4 is a perspective view of the cooling module, in a state in which the semiconductor devices are mounted, constituting the cooling device according to Embodiment 1 of the present invention. FIG. 5 is a view explaining a configuration of the cooling module used in the cooling device and flowing of coolant used in the electric power conversion apparatus according to embodiment 1 of the present invention.

As represented in FIG. 1(a), an electric power conversion apparatus 100 is attached under the car body of an electric car. As seen in FIG. 1(b), in the approximately upper half of the view illustrating the electric power conversion apparatus 100, a main circuit unit 1 including a case 1A into which a semiconductor device constituting a main circuit for converting electric power and a cooling mechanism of the semiconductor device are installed is provided. At the approximate center of the bottom face of the electric power conversion apparatus 100, a blower 2 as a cooling fan for generating wind is provided, contacting with the main circuit unit 1, for cooling by the cooling mechanism. An electrical component 3 is arranged under the main circuit unit 1 so as to surround the blower 2. Here, the electrical component 3 is an electrical part needed for configuring the electric power conversion apparatus. However, semiconductor devices mounted on cooling modules 6 and capacitors separately placed are omitted in the figure.

As seen in FIG. 1(a), in the side face of the main circuit unit 1, an aperture 1B (not illustrated in FIG. 1) through which the blower 2 draws outside air is provided on the case 1A, and a filter 1C is attached to the aperture 1B for preventing dust, etc. entering inside the main circuit unit 1. As illustrated in FIG. 3, ducts 4 as wind tunnels are provided in the main circuit unit 1 for flowing outside air from the aperture 1B to the blower 2. The outside air drawn from the aperture 1B provided in the side face of the electric car passes through the ducts 4 penetrating the main circuit unit 1, cools the semiconductor devices configuring the main circuit, and is exhausted by the blower 2 outside the lower portion of the electric car. The blower 2 in which a motor is placed at the center thereof is structured that rotors are provided on both sides of the motor. The rotors draw air from the motor side and exhaust it to the outside by the centrifugal force.

FIG. 2(a) is a perspective view of the electric power conversion apparatus 100, where the car body, the case 1A, and parts, for electrically connecting, of the electric car are omitted. A predetermined number (6 pieces, in this embodiment) of cooling modules 6, in which semiconductor devices as heat-generating elements each performing a switching operation for converting electric power are mounted, are arranged widthwise, and sets of such arranged cooling modules are provided in two rows. Capacitors 5 as a dc source for an inverter are arranged on the main circuit unit 1. Here, regarding the capacitors 5 provided on the cooling modules 6 placed in the back side of the rows, their drawing is omitted. Semiconductor devices 7 (not illustrated in FIG. 2(b)) are mounted on the cooling modules 6 with one-surfaces of the devices contacting the modules, and wiring boards 8 for electrically wiring each are connected to the other surfaces of the devices. Here, the gaps between the arranged cooling modules 6 may be set narrower if electrical insulation is secured. The rows of the cooling modules 6 are fixed to the case 1A or a fixing member configured of suitable material.

In FIG. 4, the cooling module 6 is configured with a cooling unit 6A to which a predetermined number (three pieces, in this embodiment) of semiconductor devices 7 is mounted, a heat exchanger 6B for exchanging heat between coolant exiting the cooling unit 6A and that entering there, and a radiation unit 6C for radiating heat from the coolant heated by the cooling unit 6A. The cooling unit 6A, the heat exchanger 6B, and the radiation unit 6C are arranged approximately on the same plane, in which the cooling unit 6A is placed in the vicinity of the radiation unit 6C, the heat exchanger 6B is placed over the cooling unit 6A. Although in FIG. 2(b), the state has been illustrated in which the wiring board 8 is also attached by which the semiconductor devices 7 can constitute the electrical circuit, a state in FIG. 4 is illustrated in which the wiring board 8 is detached.

As seen in FIG. 3, the radiation units 6C each are placed inside each of the ducts 4, and are cooled by wind passing through the ducts 4. Because the radiation units 6C are placed in two rows, the ducts 4 are separated to two portions inside the main circuit unit 1.

The semiconductor devices mounted on a cooling module 6 should be arranged close together in an electrical circuit such as a single-phase or single-arm of a converter or inverter. As a result, the resistance and the inductance of the electrical circuit can be reduced, and the wiring can also be made easier. A single package into which a plurality of devices has been packed may be mounted on the cooling module 6. The area of the cooling unit 6A and the radiation unit 6C of a single cooling module 6, and the number of the cooling modules 6 are determined so that all of the semiconductor devices 7 to be mounted can be mounted, an estimated amount of heat generated by the semiconductor devices 7 mounted can be dissipated from the radiation unit 6C, and the entire volume is as small as possible. Here, because the temperature of cooling air for the cooling module 6 placed closer to the aperture is lower and its cooling ability is higher, the amount of heat generated in the cooling module 6 may be set in such a way that the closer to the aperture the cooling module is, the larger the amount of heat is, and that the more distant to the aperture the cooling module is, the smaller the amount of heat is.

A configuration of the cooling module 6 is explained using FIG. 5. In the cooling unit 6A, a plurality of heat receiving tubes 6D through which the coolant flows is arranged lengthwise with a predetermined interval, are provided at a portion where the semiconductor devices 7 represented by broken lines are mounted, and the heat receiving tubes 6D are connected at their bottom ends to a single pipe 6E, and at their top ends to the heat exchanger 6B.

In the heat exchanger 6B whose outer shape is cylindrical, two partition plates 6F whose shapes are identical are provided at respective positions a predetermined distance apart from both ends of the heat exchanger. The two partition plates 6F have a predetermined number of circular holes, each of which is connected to a cylindrical pipe 6G. The interior of the heat exchanger 6B separated by the two partition plates 6F is distinguished to the inside and the outside of the pipe 6G; that is, because the interior of the pipe 6G is connected with the outside of the partition plates 6F, the interior of the heat exchanger 6B is distinguished by two portions. The heat receiving tubes 6D arranged in the cooling unit 6A are connected to the exterior of the pipes 6G in the portion sandwiched between the two partition plates 6F. The pipe GE connected to the cooling unit 6A is connected to the right-hand portion of the partition plates 6F positioned at the right side in the drawing. A pipe GH connected to the bottom of the radiation unit 6C is connected to the bottom of the just right-hand portion of the partition plates 6F positioned at the left side. A pipe 6J connected to the radiation unit 6C is connected to the left-hand portion of the partition plates 6F positioned at the left side.

A plurality of heat radiation pipes 6K arranged lengthwise with a predetermined interval is provided in the radiation unit 6C, the heat radiation pipes 6K are connected at the top thereof to the pipe 6J, and at the bottom thereof to the pipe 6H. Heat radiation fins 6L, each intervening between the heat radiation pipes 6K, are provided for increasing the heat radiation amount. The shape of the heat radiation fins 6L is determined so that cooling wind passing through the ducts 4 can be passed, pressure loss when the wind passes through the heat radiation fins 6L is within a permissible range, and the heat radiation amount is increased.

Coolant flow is also represented in FIG. 5. In the heat receiving tubes 6D included in the cooling unit 6A, the coolant is heated by the heat generated in the semiconductor devices, and then starts to boil. The coolant vapor generated by the boiling is moved toward the upper heat exchanger 6B, and the liquid coolant is also moved, with being dragged by coolant-vapor bubbles, toward the heat exchanger 6B. The coolant entering the heat exchanger 6B flows outside the pipe 6G, and after the heat of the coolant is given to that in the pipe 6G, the coolant vapor is returned to liquid; thereby, the temperature of the coolant is also decreased. The coolant from the heat exchanger 6B passes through the pipe 6H, and enters the radiation unit 6C. The temperature of the coolant entering the radiation unit 6C is further decreased with the heat being given to the air. The coolant from the radiation unit 6C enters the heat exchanger 6B after passing through the pipe 6J. The temperature of the coolant entering the heat exchanger 6B after passing through the pipe 6J, is increased with the heat, due to the coolant passing inside the pipe 6G, being given from the external coolant. The coolant from the heat exchanger 6B passes through the pipe 6E, and returns to cooling unit 6A.

The coolant boils in the heat receiving tubes 6D included in the cooling unit 6A, and moves upward, and then the moved coolant vapor returns to liquid by the cooling operation; therefore, the coolant steadily flows from the boiling portion toward the portion where the vapor returns to the liquid, which results in the coolant circulating without providing a pump. Such mechanism for circulating the coolant by utilizing the coolant boiling is also referred to as a bubble pump. By utilizing the bubble pump, a pump and its fixtures, etc. are unnecessary, and the structure of the cooling module is simplified; consequently, the maintenance is facilitated.

Regarding space saving, at least a volume occupied by the pump, etc. can be reduced by utilizing the bubble pump. Moreover, in a case of the pump, etc. being provided, the gaps between the cooling modules 6 are necessary to be determined considering the height and width of the pump, etc., and therefore the gaps between the cooling modules 6 could not be reduced enough; however, the gaps between the cooling modules 6 each become possible to be held at a thickness approximately equal to that of one of the cooling modules 6 themselves, and consequently the volume needed for cooling a predetermined amount of heat generation can be set to be less than that of a case in which a pump is provided. In a case of the heat pipe being used, a volume obtained by multiplying by the height of the heat pipe the area, on which heat-generating elements are mounted, of the cooling unit for cooling the elements was needed for the heat pipe system; on the contrary, in the present case, because ensuring the radiation-unit area corresponding to the amount of the heat generation is sufficient, and limitation is not given to the thickness of the radiation unit, by applying reduced thicknesses for the cooling unit and the radiation unit, the volume needed for cooling can be reduced. The amount of the heat generation is determined corresponding to the conversion ability of the electric power conversion apparatus, and the volume needed for cooling an equivalent amount of the heat generation can be reduced. Therefore the volume of the electric power conversion apparatus whose conversion ability is equivalent to that of a conventional apparatus can be smaller than that of the conventional one.

Because the dual-row radiation units have been arranged close to each other, a single blower is sufficient for the dual-row parts, that is, the number of parts can be reduced and consequently, the cost can be reduced, and the reliability can be improved. Even in a case of the radiation units being arranged in a single row, because the radiation units are arranged side by side, an advantage is also obtained that a single blower is sufficient for a plurality of radiation units.

Although the cooling modules have been arranged in two rows, they may be arranged in a single row or in more than two rows. The radiation units of the dual-row cooling modules have been arranged close to each other, and the dual-row cooling modules have been configured to be cooled by the single blower; however, a blower may be provided for every row of the cooling modules or for every predetermined number of the cooling modules.

Although the cooling unit and the radiation unit of the cooling module have been laterally arranged approximately in the same plane, the cooling unit and the radiation unit may be arranged to have a predetermined angle therebetween, may be arranged approximately in parallel to each other and in respective planes different from each other, or may be arranged one above the other or obliquely-and-laterally with each other.

Although a case in which the cooling device is applied to the electric power conversion apparatus mounted on the electric car has been explained, the device may be applied to an electric power conversion apparatus mounted on a machine other than an electric car, or to an apparatus other than an electric power conversion apparatus. For example, the device may be used for cooling an electrical board, etc. on which a semiconductor device that generates heat is mounted. The device may be also applied to a heat-generating element other than a semiconductor device. The cooling device according to the present invention can be applied to any heat-generating element to be cooled as long as the heat-generating element is contactable with the cooling unit.

The above description is also applicable to the other embodiments.

### Embodiment 2

In Embodiment 2, a case is represented in which the configuration in Embodiment 1 is changed so that the blower is provided for each row of the cooling modules arranged. FIG. 6 is a perspective view explaining a configuration of an electric power conversion apparatus according to Embodiment 2.

Only differences from those in FIG. 2 according to Embodiment 1 are explained. The dual-row cooling modules 6 are arranged in such a way that the radiation units 6C are separated from each other, and each blower 2 is placed in the back side of each row of the radiation units 6C as represented in the drawing.

An effect is also obtained that the cooling modules 6 can be compacted (the volume of the cooling device needed for cooling by a predetermined heat-generation amount can be reduced) similarly to that in Embodiment 1.

### Embodiment 3

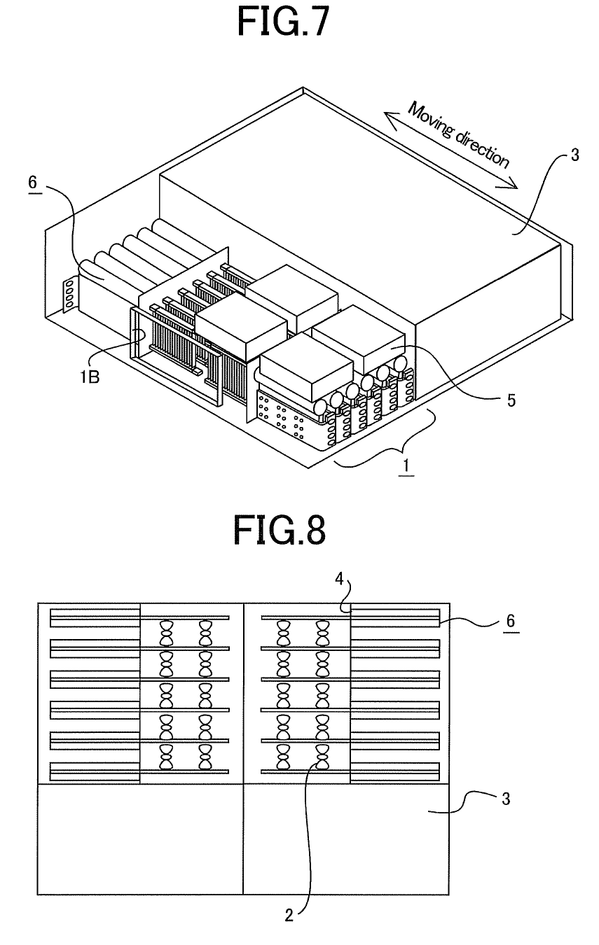

In Embodiment 3, a case is represented in which the configuration in Embodiment 1 is changed, by providing a blower for every predetermined number of cooling modules, so that the modularity of the cooling module is further improved. FIG. 7 is a perspective view explaining a configuration of an electric power conversion apparatus using a cooling device according to Embodiment 3. FIG. 8 is a plan view of the main circuit unit 1 viewed from the bottom.

Only differences from those in FIG. 2 according to Embodiment 1 are explained. Because the blowers 2 are arranged under the cooling module 1, they cannot be viewed in the perspective view. As seen from FIG. 8 as the plan view viewed from the bottom, two blowers 2 are arranged for every two cooling modules 1.

An effect is also obtained that the cooling modules 6 can be compacted similarly to that in Embodiment 1. Moreover, because a blower is provided for every predetermined number of cooling modules, an effect is also obtained that the modularity according to the set of the blower and the predetermined number of cooling modules is further improved.

### Embodiment 4

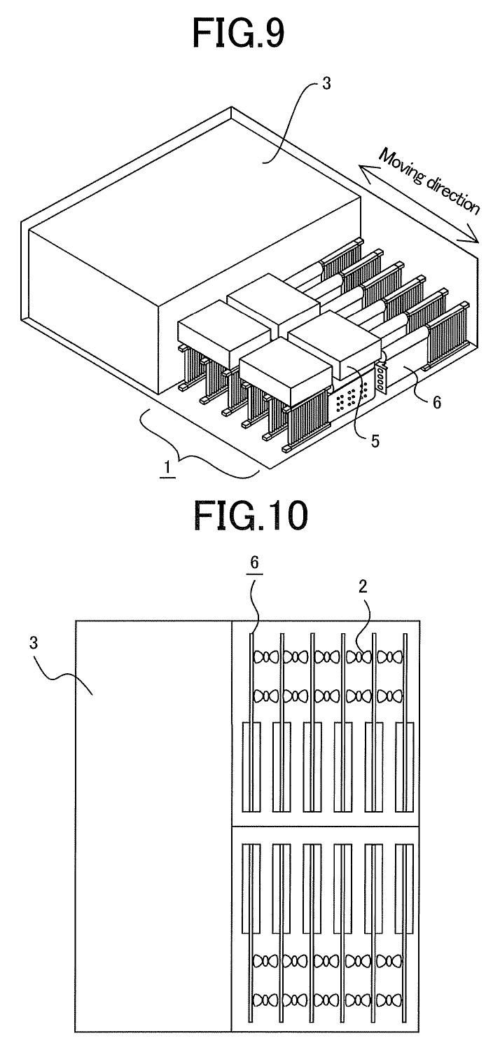

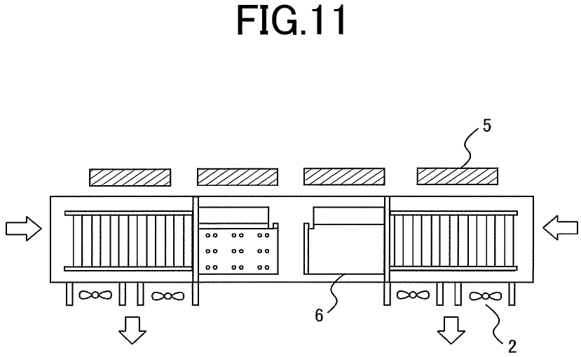

In Embodiment 4, a case is represented in which the configuration in Embodiment 3 is changed so that outside air is introduced through the both side faces of the electric car. FIG. 9 is a perspective view explaining a configuration of an electric power conversion apparatus using a cooling device according to Embodiment 4. FIG. 10 is a plan view of the main circuit unit 1 viewed from the bottom. FIG. 11 is a cross-sectional view explaining wind flow inside the main circuit unit 1.

Only differences from those in FIG. 7 and FIG. 8 according to Embodiment 3 are explained. The main circuit unit 1 is arranged perpendicular to the moving direction of the electric car, so that the radiation units 6C of the cooling modules 6 positions on a side face of the electric car. The blower 2 operates to draw outside air through the both side faces of the electric car, and then to exhaust it to the downward direction of the electric power conversion apparatus.

An effect is also obtained that the cooling modules 6 can be compacted similarly to that in Embodiment 1. Moreover, because the blower is provided for every predetermined number of cooling modules, an effect is also obtained that the modularity according to the set of the blower and the predetermined number of cooling modules is further improved. Furthermore, because outside air can be introduced through the two portions, i.e., the both side faces of the electric car, a larger amount of outside air can be drawn, which results in effect of an improved cooling efficiency.

What is claimed is:

1. A cooling device comprising:
a plurality of cooling modules having their respective cooling units for cooling heat-generating elements by coolant and radiation units for radiating heat from the coolant heated in the cooling units, said cooling modules being bubble-pump-type ones in which the coolant is circulated between the radiation units and the cooling units by the coolant being boiled in the cooling units, said radiation units being arranged side by side; and
a cooling fan for generating wind blowing the radiation units.

2. A cooling device as recited in claim 1, wherein the cooling modules are arranged in a plurality of rows so that the radiation units arranged side by side come in rows adjacent to each other.

3. A cooling device as recited in claim 1, wherein the cooling fan is provided for every predetermined number of cooling modules.

4. A cooling device as recited in claim 1, further comprising a fixing member for fixing the plurality of cooling modules on which the heat-generating elements are mounted.

5. A cooling device as recited in claim 1, further comprising a wind tunnel for allowing wind generated by the cooling fan to pass therethrough, wherein the radiation units are arranged inside the wind tunnel.
